(19) United States
(12) Patent Application Publication
(10) Pub. No.: US 2007/0070607 A1
(43) Pub. Date: Mar. 29, 2007

(54) Applied heat spreader with cooling fin

(75) Inventor: Paul Goodwin, Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group, L.P.

(21) Appl. No.: 11/234,342

(22) Filed: Sep. 23, 2005

(51) Int. Cl. H05K 7/20

(52) U.S. Cl. 361/719

(57) ABSTRACT

A heat spreader is devised with one or more extensions to increase effective surface area exposed to air. Whether air flow is forced or ambient, and where preferred high thermal conductivity materials are employed, an opportunity for enhanced thermal performance of the circuit or circuit module to be cooled is provided. In a preferred embodiment, a DIMM is inserted at least in part into a channel of a heat spreader comprised of aluminum which exhibits at least one extension in the shape of a “T” above the circuit module. Some embodiments will exhibit multiple extensions or fins while others may have only a single extension in a variety of configurations. The heat spreader is preferably devised from metallic material with high thermal conductivity and for economic and manufacturability reasons, aluminum is a preferred material choice although where higher demands are encountered, copper and other higher conductivity or non metallic materials may be employed. The heat spreader may be used to improve cooling of circuit modules of a variety of types.

### FIELD

The present invention relates to systems and methods to improve the thermal performance of high density circuit modules such as, in particular, DIMMs and related products.

### BACKGROUND

Memory expansion is one of the many fields where high density circuit module solutions provide space-saving advantages. However, as circuit density rises, the concentration of thermal energy typically increases. As thermal energy increases in concentration, the temperature of the device increases. Increased device temperature typically results in lower performance and, in extreme cases, lower reliability. This issue is particularly relevant in high density semiconductor memory solutions such as, for example, memory modules and circuits.

For example, the well-known DIMM (Dual In-line Memory Module) has been used for years, in various forms, to provide memory capacity and expansion. At the same time, however, circuit density and stringent profile requirements have increased the thermal demands on DIMMs and related modules and products.

Attempts to resolve or mitigate the heat issue in circuit modules have met partial success. Such techniques typically require, however, added power consumption or relatively expensive subsystems. For example, higher performance computers such as servers typically incorporate a cooling fan and associated computer box venting to increase airflow over high heat integrated circuitry such as microprocessors and memory modules. The fans increase weight however and consume energy.

For a given thermal load, the interplay between airflow, effective circuit module surface area and materials thermal conductivity are substantial determinates of circuit module thermal performance. Consequently, solutions that bolster these predicates to thermal performance are more likely to result in efficacious systems and methods for improving thermal performance of circuit modules.

Some of these determinates are, however, fixed. For example, there is already a very large installed base of circuit modules and these are installed in a variety of machines where the aggregate air flow and the employed module materials are already determined. Consequently, what is needed is a system and method to readily increase thermal performance of high performance circuit modules and ICs with low cost and high efficiency.

### SUMMARY

A heat spreader is devised with one or more extensions to increase effective surface area exposed to air. Consequently, whether air flow is forced or ambient, and where preferred high thermal conductivity materials are employed, an opportunity for enhanced thermal performance of the circuit or circuit module to be cooled is provided.

In a preferred embodiment, a DIMM is inserted at least in part into a channel of a heat spreader comprised of aluminum which exhibits at least one extension in the shape of a “T” above the circuit module. Some embodiments will exhibit multiple extensions or fins while others may have only a single extension in a variety of configurations. The heat spreader is preferably devised from metallic material with high thermal conductivity and for economic and manufacturability reasons, aluminum is a preferred material choice although where higher demands are encountered, copper and other higher conductivity or non metallic materials may be employed. The heat spreader may be used to improve cooling of circuit modules of a variety of types such as DIMMs for example, and may be profitably employed with the large installed base of circuit modules in use in computer or other applications.

### BRIEF DESCRIPTION OF THE DRAWINGS

FIG. 1 is an exploded depiction of a typical exemplar circuit module and an associated heat spreader in accordance with a preferred embodiment of the present invention.

FIG. 2 illustrates a typical circuit module fitted with a heat spreader in accordance with a preferred embodiment of the present invention.

FIG. 3 is a cross-sectional view of a circuit module fitted with a heat spreader in accordance with a preferred embodiment of the present invention.

FIG. 4 is an exploded view of a typical circuit module and a heat spreader in accordance with a preferred embodiment of the present invention.

FIG. 5 illustrates a typical circuit module fitted with a heat spreader in accordance with a preferred embodiment of the present invention.

FIG. 6 is a cross-sectional view of a circuit module and heat spreader in accordance with a preferred embodiment of the present invention.

FIG. 7 is cross-sectional view of a circuit module populated with stacks and employed with a heat spreader in accordance with a preferred embodiment of the present invention.

FIG. 8 is an exploded view of a circuit module and a heat spreader in accordance with a preferred embodiment of the present invention.

FIG. 9 illustrates a circuit module fitted with a heat spreader in accordance with a preferred embodiment of the present invention.

### DETAILED DESCRIPTION OF THE PREFERRED EMBODIMENTS

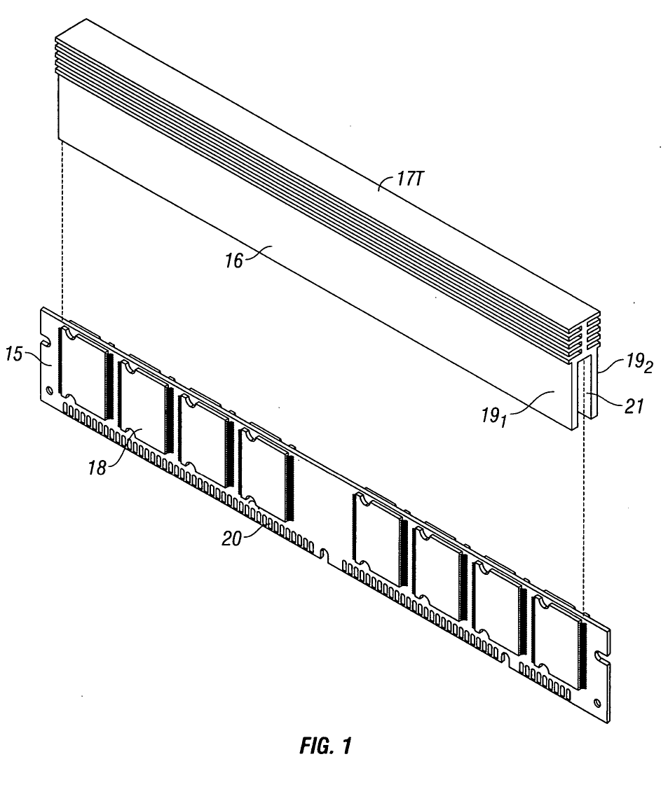

FIG. 1 is an exploded depiction of a typical exemplar circuit module 15 which is populated with at least ICs 18 and a heat spreader 16 in accordance with a preferred embodiment of the present invention. Heat spreader 16 exhibits extensions 17T which, in this example, are configured as multiple iterations of a “T” configuration. Heat spreader 16 is comprised of thermally conductive material such as, for example, aluminum or, where high thermal demands are presented, copper or copper alloy. Other embodiments may employ other thermally conductive materials such as, for example, thermally conductive plastics or carbon based materials with appropriate thermal conductivity.

Heat spreader 16 provides a system for reducing thermal loading of circuit module 15. Extensions 17T may be configured in a variety of dimensions and configurations with the illustrated multiple “T” configuration having been devised to increase effective surface area of module 15 with a thermally-conductive material. Consequently, two important determinates in thermal performance (thermal conductivity and surface area) are enhanced by heat spreader 16.

Heat spreader 16 is preferably thermally bonded to at least some of the constituent ICs 18 of module 15. This bonding may be realized with applied pressure, adhesives or thermal grease, for example.

As shown in FIG. 1, module 15 is inserted at least in part into channel 21 of module 15 and preferably there is in thermal contact between heat spreader 16 and at least one IC on each side of module 15. The invention can be employed with a variety of circuit modules including simple DIMMs such as the circuit module 15 depiction of FIG. 1 or more complex circuit modules such as the widely known fully-buffered DIMM that will employ an advanced memory buffer which itself generates a significant amount of thermal energy. As those of skill will recognize the broad utility after appreciating this specification,

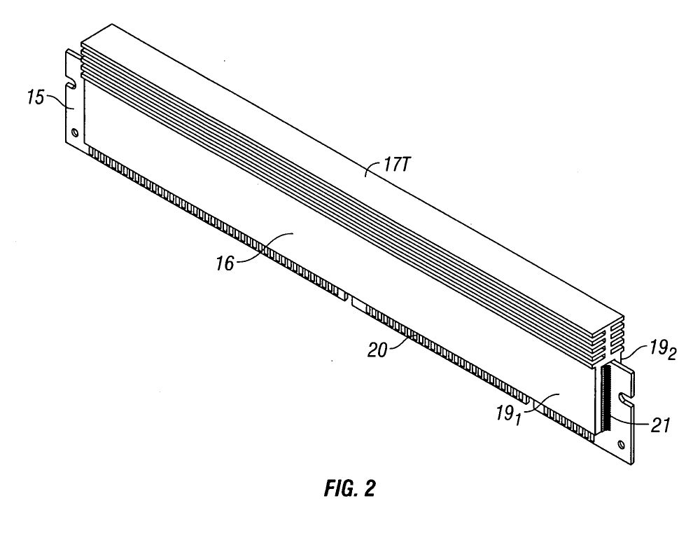

FIG. 2 depicts heat spreader 16 in place over an exemplar module 15 which may be any of the large variety of modules with similar configurations such as the following non-limiting examples: registered DIMMs, unbuffered DIMMs, FB-DIMMs, graphics modules and communications modules.

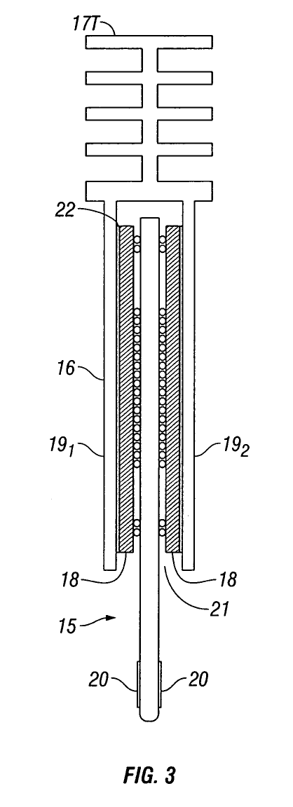

FIG. 3 is a cross-sectional view of a module 15 fitted with heat spreader 16 with which module 15 is in thermal contact through thermal grease 22. As earlier said, the thermal contact between heat spreader 16 and the ICs of module 15 may be by direct contact, through an intermediary such as, for example, thermal grease, or where a more permanent installation is desired, by thermal adhesives, for example.

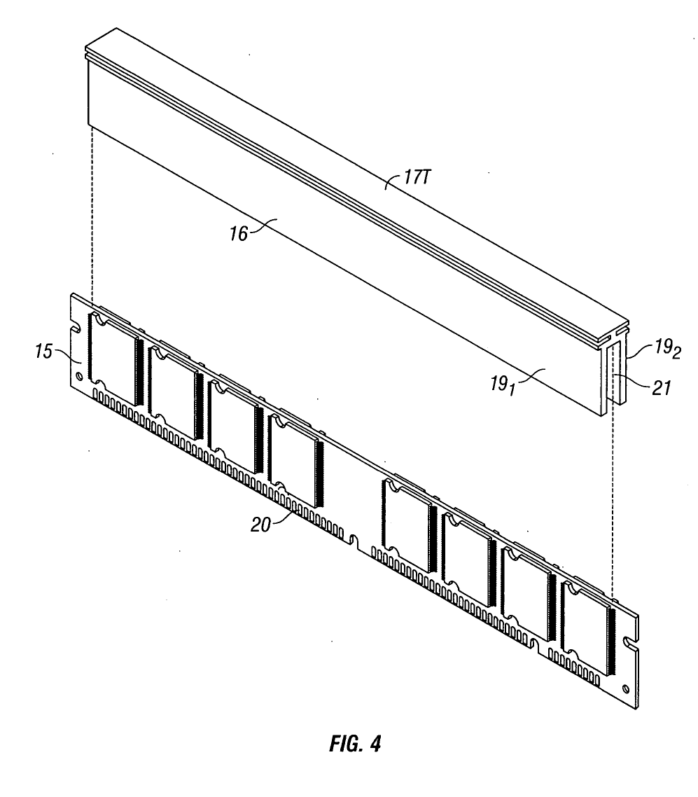

FIG. 4 is an exploded depiction of a heat spreader 16 in conjunction with an exemplar module 15. Heat spreader 16 as shown in FIG. 4 exhibits a single primary “T” configured extension 17T. The heat spreader of particular embodiments of the present invention with the exhibited “T”-configured extension 17T provide an improved heat extraction system and method to alleviate the thermal accumulation issues of contemporary module design and operation. Other shapes for extension 17T are also possible. The embodiment of FIG. 4 should be considered therefore, to be merely a preferred example of a heat spreader according to the invention that exhibits a single extension. Prior art heat clips do not typically provide sufficient surface area to compensate for appreciable thermal loading of module 15 thus the addition of one or more extensions as disclosed herein provide improved heat transfer opportunities.

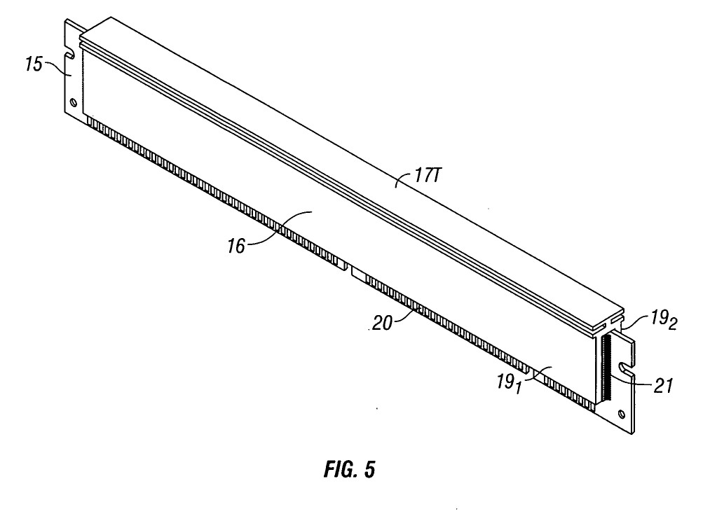

FIG. 5 illustrates heat spreader 16 in place over module 15 which, as earlier described with reference to FIG. 2 may be any one of a variety of circuit modules.

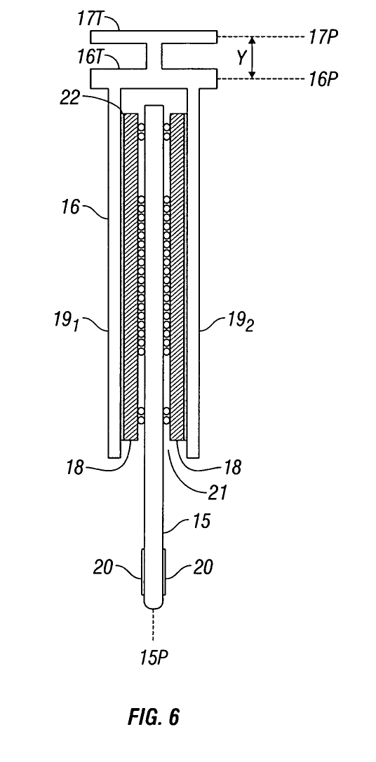

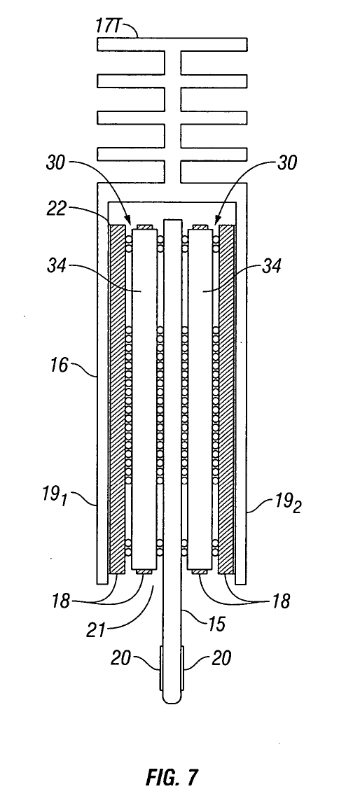

FIG. 6 is a cross-sectional view of a combination of module 15 and heat spreader 16 in accordance with a preferred embodiment of the present invention. In FIG. 6 three planes are identified as follows: 17P—the plane substantially coincident with which extension 17T lies; 16P—the plane substantially coincident with which top shelf 16T of heat spreader 16 lies; and plane 15P—the plane substantially coincident with and about which module 15 is oriented. Top shelf 16T of heat spreader 16 may but need not extend outward beyond the lateral surfaces 19₁ and 19₂ of heat spreader 16. The depicted cross-section of FIG. 6 shows a top shelf 16T that extends beyond lateral surfaces 19₁, and 19₂ while top shelf 16T of heat spreader 16 depicted in FIG. 7 does not extend beyond the lateral surfaces 19₁ and 19₂.

There is also depicted in FIG. 6 a distance “Y” between plane 17P and 16P indicating that extension 17T is distanced from top shelf 16T of heat spreader 16. The distance Y is not critical to the invention nor is the maintenance of parallel orientation between shelf 16T and extension 17T but more preferred embodiments will exhibit a space between extension 17T and shelf 16T of heat spreader 16 that is identified by the distance Y and preferred extensions will exhibit the “T” shape shown in the figures but, as those of skill will recognize, the “T” configuration is not essential to the invention.

FIG. 7 depicts an embodiment in accordance with the present invention in which multiple extensions 17T are shown each of which is distanced from shelf 16T of heat spreader 16. Module 15 in FIG. 7 is populated with exemplar stacks 30. The depicted stacks 30 employ form standards 34 as described in U.S. Pat. No. 6,914,324 issued Jul. 5, 2005 which is hereby incorporated by reference herein. A variety of different packaged ICs may however be employed on circuit modules and used with the heat spreader of the invention as should be apparent to those of skill after appreciating this disclosure.

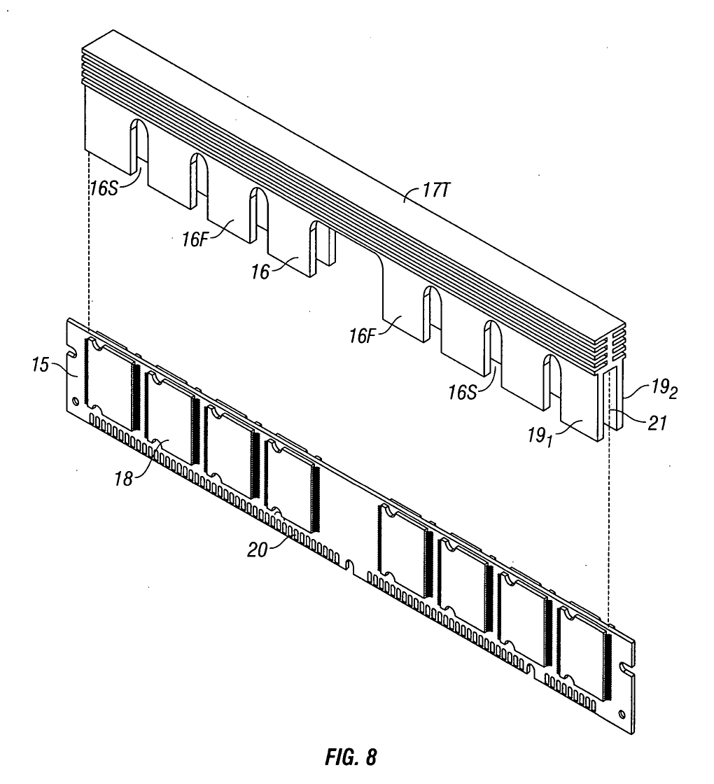

FIG. 8 depicts an exploded view of a heat spreader 16 that exhibits slots 16S that generally correspond to the spaces between ICs of the module with which heat spreader 16 is employed. Those of skill will recognize that slots 16S may be disposed in any of a variety of locations along one or both sides of heat spreader 16 and may number from one to many. The presence of slots 16S in lateral sides 19₁, and 19₂ create fingers 16S in lateral sides 19₁, and 19₂ and therefore, a channel 21 of heat spreader 16 and first and second lateral sides 19₁, and 19₂ may be comprised of facing fingers 16S.

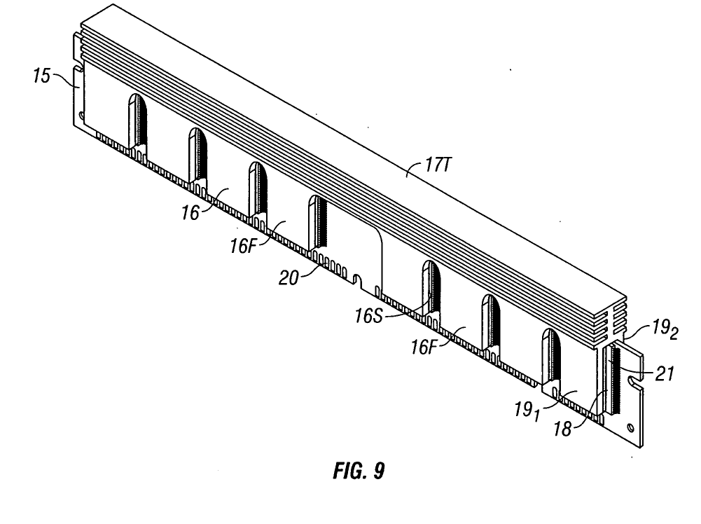

FIG. 9 depicts an exemplar module that exhibits multiple extensions and slotted lateral sides that is disposed in position over an exemplar module 15 to place module 15 at least in part into channel 21. Multiple extensions 17T are shown in the depiction of FIG. 9.

The present invention may be employed to advantage in a variety of applications and environment such as, for example, in computers such as servers and desktop computers by being employed where circuit modules are employed. Other computing devices may also employ the present invention to advantage.

Although the present invention has been described in detail, it will be apparent to those skilled in the art that many embodiments taking a variety of specific forms and reflecting changes, substitutions and alterations can be made without departing from the spirit and scope of the invention. Therefore, the described embodiments illustrate but do not restrict the scope of the claims.

1. A method for cooling a circuit module populated with ICs, the method comprising the steps of:
providing a heat spreader having a channel formed by first and second lateral sides of the heat spreader, the heat spreader being comprised of thermally-conductive material and configured to exhibit a heat spreader shelf disposed generally coincident with a first plane and an extension disposed generally coincident with a second plane, the extension being distanced from and above the heat spreader shelf; and
disposing the circuit module at least in part, into the channel of the heat spreader to establish thermal connection between the heat spreader and at least some of the ICs of the circuit module.

2. The method of claim 1 in which the circuit module is a DIMM.

3. The method of claim 2 in which the step of establishing thermal connection between the heat spreader and the DIMM is realized with thermal grease.

4. The method of claim 2 in which the heat spreader that is provided exhibits more than one extension.

5. The method of claim 2 in which the step of establishing the thermal connection between the heat spreader and the DIMM is realized through direct contact between the heat spreader and at least some of the ICs that populate the DIMM.

6. The method of claim 2 in which the first and second lateral sides of the heat spreader are slotted.

7. The method of claim 6 in which the first and second lateral sides of the heat spreader are comprised of fingers that are in thermal connection with at least some of the ICs of the DIMM.

8. The method of claim 2 in which the DIMM is a fully-buffered DIMM.

9. The method of claim 2 in which the DIMM is installed in a computer.

10. The method of claim 2 in which the heat spreader that is provided is comprised of aluminum.

11. The method of claim 6 in which the heat spreader with slotted first and second lateral sides is comprised of aluminum.

12. The method of claim 11 in which the DIMM is a fully-buffered DIMM.

13. The method of claims 1, 2, 4, 6, 7, 8, 9, or 10 in which the extension is configured as a “T”.

14. A heat spreader comprising:
thermally-conductive material configured to exhibit a channel for receiving a circuit module, the channel being formed on each side by first and second lateral sides distanced by a shelf above and distanced from which shelf at least one primary extension configured to present a “T” shape is exhibited.

15. The heat spreader of claim 14 further comprising at least another extension disposed above the primary extension.

16. The heat spreader of claim 14 in which at least one of the first and second lateral sides is slotted.

17. The heat spreader of claim 16 in which the first and second lateral sides are comprised of fingers.

18. The heat spreader of claim 14 in which the thermally-conductive material is aluminum.

19. The heat spreader of claim 16 in which the thermally-conductive material is aluminum.

20. The heat spreader of claim 14 or 16 in which the thermally-conductive material is not metallic.

21. The heat spreader of claim 14 in which the shelf extends beyond the first and second lateral sides of the heat spreader.

22. A heat spreader comprising:
thermally-conductive material configured to exhibit a channel for receiving a circuit module, the channel being formed on each side by first and second lateral sides distanced by a shelf substantially along and coincident with a first plane above which shelf and distanced from there is at least one primary extension substantially along and coincident with a second plane.

23. A system for cooling a DIMM populated with ICs, the system comprising:
a DIMM inserted at least in part into the channel of the heat spreader of claim 22 to establish thermal connection between at least two of the ICs that populate the DIMM and heat spreader.

24. The system of claim 23 in which the thermal connection established between the heat spreader and the at least two ICs of the DIMM is realized through thermal grease.

25. The system of claim 23 in which the primary extension is configured to present a “T” shape.

26. The system of claim 23 in which the heat spreader exhibits at least one supplemental extension above the primary extension.

27. The system of claim 23 in which the heat spreader is comprised of aluminum.

28. The system of claim 23 in which the DIMM is a fully-buffered DIMM.

29. The system of claim 28 in which the heat spreader is comprised of non-metallic material.
